(19) United States
(12) Patent Application Publication
(10) Pub. No.: US 2013/0285098 A1
(43) Pub. Date: Oct. 31, 2013

(54) PATTERNED SUBSTRATE AND LIGHT EMITTING DIODE STRUCTURE

(71) Applicant: CRYSTALWISE TECHNOLOGY INC, MIAOLI COUNTY (TW)

(72) Inventors: BO-WEN LIN, MIAOLI COUNTY (TW); SHIH-CHIEH HSU, MIAOLI COUNTY (TW); CHUN-YEN PENG, MIAOLI COUNTY (TW); WEN-CHING HSU, MIAOLI COUNTY (TW)

(73) Assignee: CRYSTALWISE TECHNOLOGY INC, MIAOLI COUNTY (TW)

(21) Appl. No.: 13/871,021

(22) Filed: Apr. 26, 2013

(30) Foreign Application Priority Data
Apr. 27, 2012 (TW) 101115238

(51) Int. Cl. H01L 33/22

(52) U.S. Cl. CPC H01L 33/22
USPC 257/98; 428/180

(57) ABSTRACT

A patterned substrate includes a substrate and a plurality of protrusions. The protrusions are formed on the substrate. Each protrusion has a top face and a base. Each pair of immediately adjacent protrusions is minimally parted by 0 to 0.2 μm. When the distance between the adjacent protrusions falls as 0 μm, the bases thereof contact each other. A horizontal and a vertical light emitting diode structures using the patterned substrate are also discussed.

### BACKGROUND

1. Field of the Invention

The instant disclosure relates to a substrate and a light emitting diode; in particular, to a patterned substrate and a light emitting diode using the same.

2. Description of Related Art

Light Emitting Diode (LED) is a lighting unit made of semiconductors. LED has two electrode terminals. When a voltage is applied to the terminals, small amount of current goes through LED and the combination of electrons and holes excites the rest energy as a form of light. This is the mechanism of LED light emitting. LED is different from the conventional incandescent light because LED is luminescence. More specifically, LED consumes less power, has longer life span and responses rapidly. On/Off time is relatively short for LED lighting. In addition, the size of LED is small and therefore suitable for mass production. It is easier to meet the practical demand such as smaller volume or matrix arrangement. The luminance of LED has been improved through the time. LED has been widely implemented as an indicator or on a display unit in information, communication and consumer electronics.

The conventional LED is flat on the top face and the substrate is a plane parallel to the top face. Hence, when light is emitted, a portion of the light goes through the top face and scatters out while total internal reflection occurs to another portion of the light because the incident angle is above the critical angle. This portion of light cannot travels through to the exterior because the LED surface and the substrate are parallel planes. The luminance is reduced and the trapped light accumulates inside the LED and converts to heat. The high temperature within the LED may compromise the overall performance and stability. A patterned Sapphire Substrate (PSS) is used to solve this problem and epitaxy is conducted on the PSS to form the LED. The patterned PSS facilitates light scattering to increase the light output and the overall LED luminance.

### SUMMARY OF THE INVENTION

The instant disclosure provides a patterned substrate and LED structures using the same. Due to the presence of gaps among protrusions, the light is well distributed and scatters out from the LED and therefore the overall luminance is increased.

According to one exemplary embodiment of the instant disclosure, the patterned substrate includes a substrate and a plurality of protrusions formed on the substrate. Each protrusion has a top face and a base. Each pair of immediately adjacent protrusions is minimally spaced by 0 to 0.2 μm. When the minimal distance between the pair of immediately adjacent protrusions is 0 μm, the bases thereof contact each other.

The instant disclosure also provides a LED structure including a substrate, a plurality of protrusions formed on the substrate, a first semiconductor layer, a light emitting layer, a second semiconductor layer, a first electrode and a second electrode. Each protrusion has a top face and a base. Each pair of immediately adjacent protrusions is minimally spaced by 0 to 0.2 μm and a gap is defined therebetween. When the minimal distance between the pair of immediately adjacent protrusions is 0 μm, the bases thereof contact each other. The first semiconductor layer laminates on the substrate and covers the protrusions. The light emitting layer laminates on a portion of the first semiconductor layer. The second semiconductor layer laminates on the light emitting layer. The first electrode is disposed on the remaining portion of the first semiconductor layer in which the light emitting layer does not cover. The second electrode is disposed on the second semiconductor layer.

The instant disclosure further provides a LED structure including a substrate, a plurality of protrusions formed on the substrate, a first semiconductor layer, a light emitting layer, a second semiconductor layer and a first electrode. Each protrusion has a top face and a base. Each pair of immediately adjacent protrusions is minimally spaced by 0 to 0.2 μm and a gap is defined therebetween. The first semiconductor layer laminates on the substrate and covers the protrusions. The light emitting layer laminates on the first semiconductor layer. The second semiconductor layer laminates on the light emitting layer. The first electrode is disposed on the second semiconductor layer. When the minimal distance between the pair of immediately adjacent protrusions is 0 μm, the bases thereof contact each other.

In short, the horizontal LED, which is fabricated with the patterned substrate of the instant disclosure, has higher luminance because the gaps are retained. The gaps among the protrusions facilitate light emitting from the LED and as a result light output is increased. In addition, the vertical LED, which is fabricated with the patterned substrate of the instant disclosure, is more cost effective. The gaps serve as channels for filling chemicals and then separating the substrate and the LED structure. In this regard, the conventional laser peeling can be effectively replaced by the chemical peeling to reduce cost.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE DRAWINGS

FIG. 1 is a cross-sectional diagram illustrating a patterned substrate of the instant disclosure;

FIG. 2 is a top schematic view showing a base corner contacting another base corner of protrusions on a patterned substrate of the instant disclosure;

FIG. 3 is a top schematic view showing a base corner contacting a base edge of protrusions on a patterned substrate of the instant disclosure;

FIG. 4 is a top schematic view showing protrusion array on a patterned substrate of the instant disclosure;

FIG. 5 is a top schematic view showing alternative arrangement of protrusions on a patterned substrate of the instant disclosure;

FIG. 6 is a perspective view showing a base edge contacting another base edge on a patterned substrate of the instant disclosure;

FIG. 7 is a cross-sectional view of a horizontal LED structure;

FIG. 8 is a cross-sectional view of a vertical LED substrate before peeling off; and

FIG. 9 is a cross-sectional view showing a vertical LED structure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

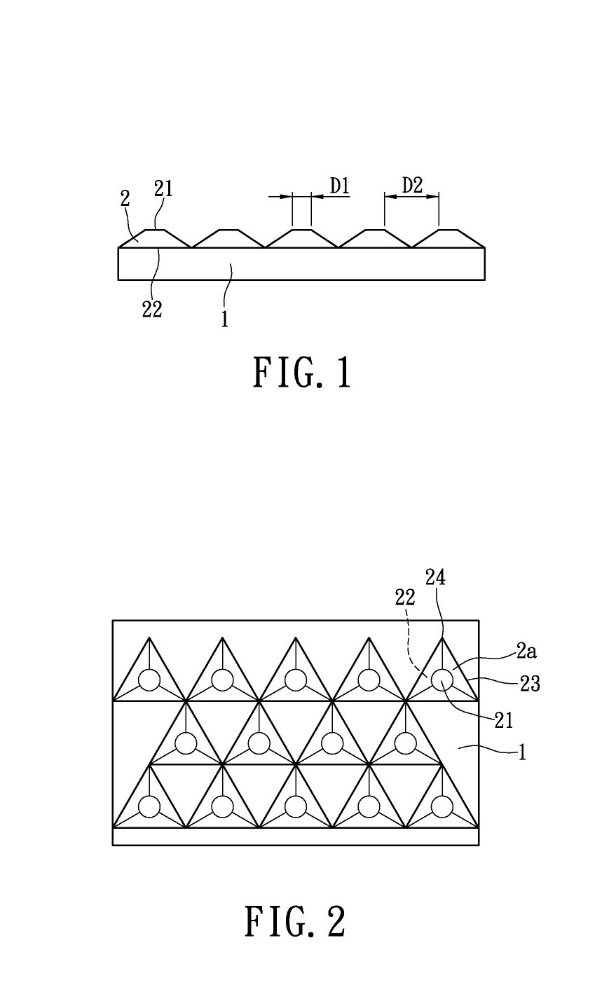

Please refer to FIG. 1. The instant disclosure provides a patterned substrate including a substrate 1 and a plurality of protrusions 2. The protrusions 2 extend from the substrate 1. Each protrusion 2 has a top face 21 and a base 22. The top face 21 of the protrusion 2 may be configured to a circle, triangle, diamond, polygonal configuration or any other geometric configurations and the instant disclosure is not limited thereto. The protrusions 2 are attached to the substrate via the base 22. The minimum distance between each pair of the immediately adjacent protrusions 2 is between 0 to 0.2 μm. However, when the pair of immediately adjacent protrusions 2 is parted by 0 μm, the two bases 22 of the protrusions 2 contacts one another. The patterned substrate may be sapphire substrate, silicone substrate or silicone carbide, and the instant disclosure is not limited thereto.

D₁ is designated as the top face diameter of the protrusion 2. D₂ is designated as the distance between two top faces of each immediately adjacent pair of protrusions 2. The ratio of D₁/D₂ ranges between 1/5 to 5. D2 is equal to or smaller than 10 μm and preferably falls between 0.3 to 2.5 μm. The protrusions 2 may be defined by dry etching or wet etching or the combination thereof and the instant disclosure is not limited thereto. The difference of fabrication process between the instant disclosure and the conventional substrate lies in etching conditions. In the instant disclosure, the wet etching process is slightly altered, for example, the etching formula and reaction time, and therefore the bases 22 of protrusions 2 are contacting or narrowly parted to each other. In addition, the spatial arrangement of the protrusions 2 is not the C-plane, which is prone to epitaxial growth. Hence, epitaxy occurs in a relatively low rate among protrusions 2. In the case of epitaxy, the epitaxial parameters can be adjusted such that the crystalline overlayer is accumulated from the top face 21 and the gaps among protrusions 2 are intact.

Thus, the horizontal LED using the patterned substrate of the instant disclosure retains the gaps and the light extraction efficiency is increased. More specifically, the gaps are filled with air. In this regard, when the light is emitted from the horizontal LED and travels to the boundary of the gaps, the different refraction rates allow the light for reflecting. The light ray, which may be bounced back to the substrate, is now affected to change the propagation towards the exterior. Furthermore, epitaxy is less likely to occur among the protrusions 2 because the protrusions 2 are not the typical C-plane. Foreign substances are prevented from forming among the protrusions 2 and therefore defects are reduced.

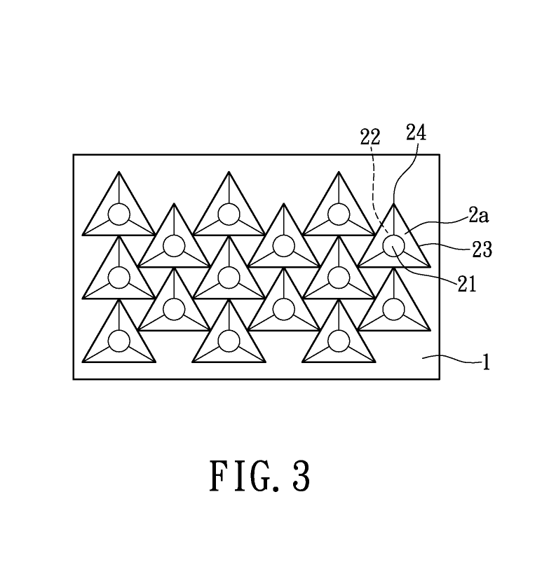

Please refer to FIGS. 2 and 3. In FIG. 2, the protrusions 2a resemble triangular pyramids. However, the protrusions 2a may resemble any polyhedrons and the geometric configuration thereof is not limited thereto. The protrusions 2a may be square pyramid, pentagonal pyramid, hexagonal pyramid or octagonal pyramid. Preferably, the protrusions 2a are triangular pyramids or hexagonal pyramid. Specifically, the top face 21 of the protrusion 2a is truncated flat. The base 22 defines a plurality of base corners 24 and a plurality of base sides 23. If the protrusion 2a is a triangular pyramid, there are three base corners 24 and three base sides 23. If the protrusion 2a is a hexagonal pyramid, there are six base corners 24 and six base sides 23.

As shown in FIG. 2, each base corner 24 of the protrusion 2a contacts or is proximate to the neighboring base corners 24 of protrusions 2a. The distance between each pair of immediately adjacent base corners 24 ranges between 0 to 0.2 μm. If the base corners 24 are parted by 0 μm, the base corners 24 contact each other.

As shown in FIG. 3, the base corners 24 of each protrusion 2a may contact or is proximate to the base sides 23 of the neighboring protrusion 2a. The distance between each pair of immediately adjacent base corner 24 and base side 23 ranges between 0 to 0.2 μm. If the base corner 24 and base side 23 are parted by 0 μm, the base corner 24 contacts the base side 23 as being contiguous. In the instant disclosure, the abovementioned configurations may exist at the same time. That is to say, in another embodiment, a number of the base corners 24 may contact each other and meanwhile a number of base corners 24 and base sides 23 may be in contact.

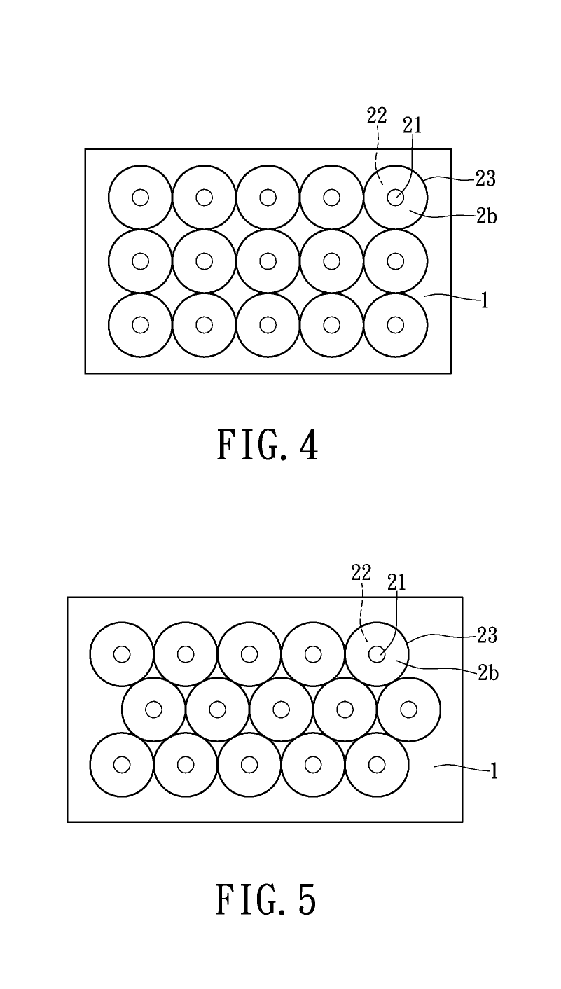

Please refer to FIGS. 4 and 5. Each protrusion 2b resembles a cone. The top face 21 is truncated flat. The base 22 defines a round edge 23. The distance between each pair of immediately adjacent base edges 23 of the protrusions 2b ranges between 0 to 0.2 μm. In other words, each base edge 23 contacts or is proximate to the neighboring base edges 23. As shown in FIG. 4, the protrusions 2b are arranged in a square array. Furthermore, the protrusions 2b are aligned to form a matrix. As shown in FIG. 5, the protrusions 2b are in alternative arrangement. Specifically, the protrusions 2b are offset by approximately half a protrusion 2b and arranged in an alternative fashion.

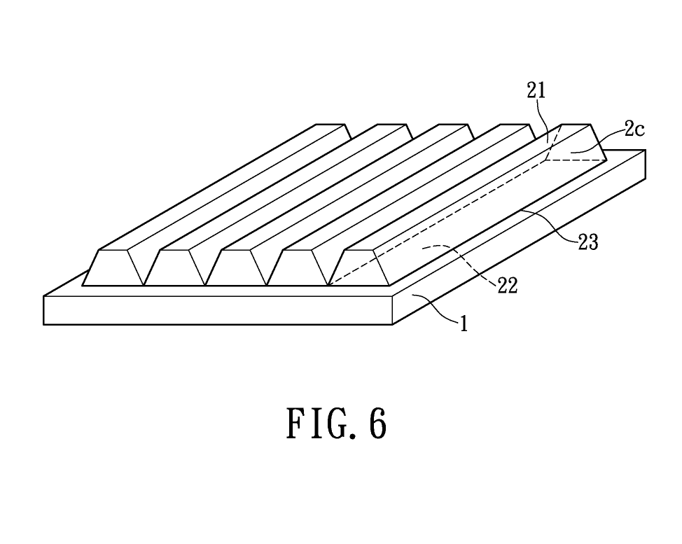

Please refer to FIG. 6. Each protrusion 2c resembles an elongated trapezoidal body. The top face 21 is truncated flat. The lengthwise sides of each base 22 define two base sides 23. The distance between each pair of immediately adjacent base sides 23 ranges between 0 to 0.2 μm. That is to say, the two base sides 23 of each protrusion 2c contacts or are in proximate to the neighboring base sides 23.

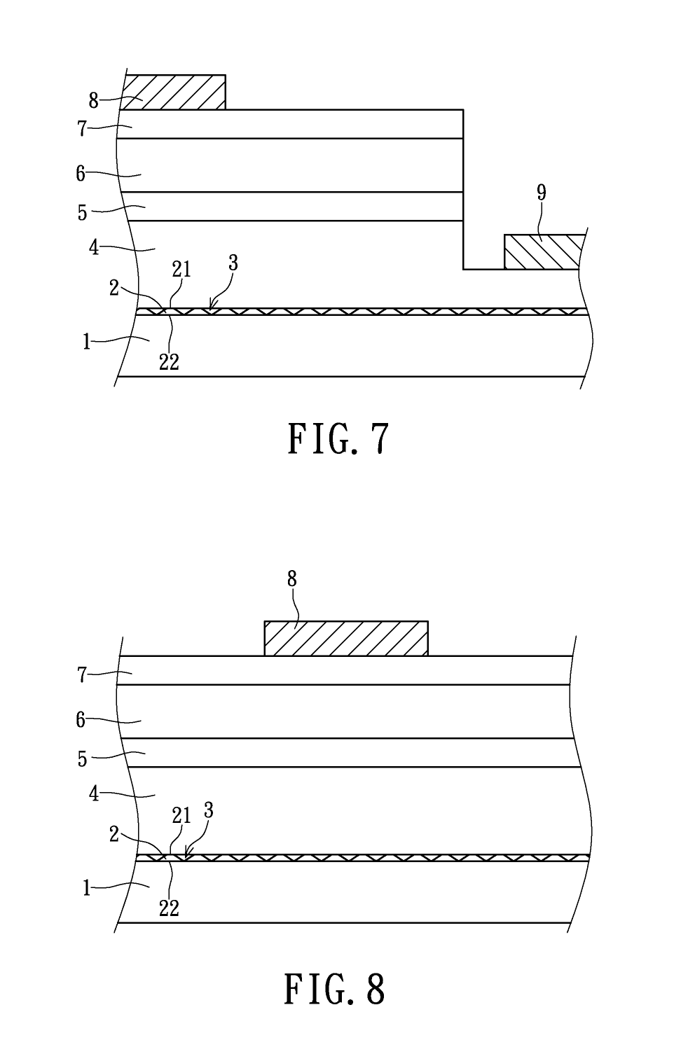

Please refer to FIG. 7. The instant disclosure also provides a LED structure including a substrate 1, a plurality protrusions 2, a first semiconductor layer 4, a light emitting layer 5, a second semiconductor layer 6, a first electrode 8 and a second electrode 9. The LED structure is a horizontal LED.

The protrusions 2 are formed on the substrate 1. Each protrusion 2 has a top face 21 and a base 22. The minimum distance between each pair of the immediately adjacent bases 22 ranges between 0 to 0.2 μm. Also, each pair of immediately adjacent protrusions 2 defines a gap 3 therebetween such that the protrusions 2 are spaced apart. Due to the presence of the gaps 3, the light extraction efficiency is promoted. The light intensity increases as well to obtain better luminance. When the distance between two adjacent protrusions 2 falls as 0 μm, the bases 22 of these protrusions 2 contact each other. The patterned substrate may be made of sapphire, silicone gel or silicone carbide and the instant disclosure is not limited thereto.

The first semiconductor layer 4 laminates on the substrate 1 and the protrusions 2 are covered thereby. A portion of the first semiconductor layer 4 is laminated by the light emitting layer 5, and the second semiconductor layer 6 laminates on the light emitting layer 5. The first electrode 8 is disposed on the second semiconductor layer 6. The second electrode 9 is disposed on the remaining area of the first semiconductor layer 4 in which the light emitting layer 5 does not cover. The contacting layer 7 interposes between the second semiconductor layer 6 and the first electrode 8 and the LED structure is completed.

The protrusions 2 may resemble polyhedrons and the top face 21 is truncated flat. The base 22 defines a plurality of base corners 24 and a plurality of base sides 23. The base corners 24 of each protrusion 2 contact or are proximate to the neighboring base corners 24 or base sides 23. Alternatively, each protrusion 2 resembles an elongated trapezoidal body. The top face 21 is truncated flat. The lengthwise sides of each base 22 define two base sides 23. The two base sides 23 of each protrusion 2 contact or are proximate to the neighboring base sides 23. Still another, each protrusion 2 resembles a cone. The top face 21 is truncated flat. The base 22 defines a round edge 23. Each base edge 23 contacts or is proximate to the neighboring base edges 23. The protrusions 2 can be arranged in matrix or in alternative.

Please refer to FIG. 8. The instant disclosure provides another LED structure including a substrate 1, a plurality of protrusions 2, a first semiconductor layer 4, a light emitting layer 5, a second semiconductor layer 6 and a first electrode 8. The LED structure is a vertical LED before peeling off the substrate.

The protrusions 2 are formed on the substrate 1. Each protrusion 2 has a top face 21 and a base 22. The minimum distance between each pair of the immediately adjacent bases 22 ranges between 0 to 0.2 μm. Also, each pair of immediately adjacent protrusions 2 defines a gap 3 therebetween such that the protrusions 2 are spaced apart. When the distance between two adjacent protrusions 2 falls as 0 μm, the bases 22 of these protrusions 2 contact each other. The patterned substrate may be made of sapphire, silicone or silicone carbide and the instant disclosure is not limited thereto.

The first semiconductor layer 4 laminates on the substrate 1 and the protrusions 2 are covered thereby. The first semiconductor layer 4 is laminated by the light emitting layer 5, and the second semiconductor layer 6 laminates on the light emitting layer 5. The first electrode 8 is disposed on the second semiconductor layer 6. The contacting layer 7 interposes between the second semiconductor layer 6 and the first electrode 8.

The protrusions 2 may resemble polyhedrons and the top face 21 is truncated flat. The base 22 defines a plurality of base corners 24 and a plurality of base sides 23. The base corners 24 of each protrusion 2 contact or are proximate to the neighboring base corners 24 or base sides 23. Alternatively, each protrusion 2 resembles an elongated trapezoidal body. The top face 21 is truncated flat. The lengthwise sides of each base 22 define two base sides 23. The two base sides 23 of each protrusion 2 contact or are proximate to the neighboring base sides 23. Still another, each protrusion 2 resembles a cone. The top face 21 is truncated flat. The base 22 defines a round edge 23. Each base edge 23 contacts or is proximate to the neighboring base edges 23. The protrusions 2 can be arranged in matrix or in alternative.

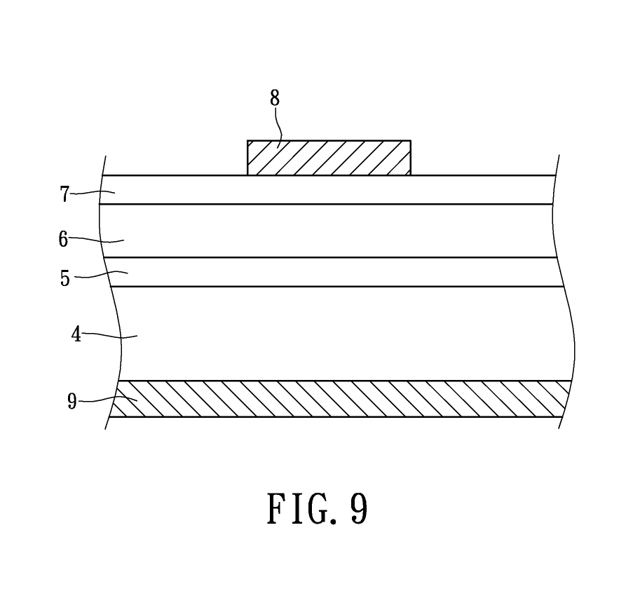

Please refer to FIG. 9. The substrate 1 is peeled off from the first semiconductor layer 4 by chemical or laser peeling and the instant disclosure is not limited to the peeling method. Preferably, the substrate 1 is peeled off by chemical peeling. Subsequently, a second electrode 9 is laminated to the first semiconductor layer 4 to replace the position of substrate 1 and the vertical LED is completed. In the chemical peeling, the gaps 3 serve as channels for filling the chemicals such that the chemical reaction takes place to allow the substrate 1 and the first semiconductor layer 4 for separating. The chemical peeling is more cost effective compared to the conventional laser peeling.

In the abovementioned fabrication method, the patterned substrate does not remain on the vertical LED. However, after the separation of the substrate 1 and the first semiconductor layer 4, the evidence of the previous existence of the patterned substrate can be known by the defect density. The inspection method is further elaborated herein. The second electrode 9 is removed and the bottom of the first semiconductor layer 4 is polished or ground. The Threading Dislocation Density (TDD) or Etched Pits Densities (EPDs) is used to determine the defect density. The original boundary between the first semiconductor layer 4 and the substrate 1 is uneven if the vertical LED is fabricated with the patterned substrate of the instant disclosure. Specifically, the defect density of the regions in which the protrusions 2 contact is lower whereas the defect density of the regions in which the protrusions 2 do not contact is higher. In this regard, it can be determined whether to implement the patterned substrate of the instant disclosure to the vertical LED. However, the inspection method is not limited to the abovementioned method.

In summary, the C-plane is formed on the top face and the epitaxy occurs therefrom. Therefore among the protrusions epitaxy is less likely to occur and the gaps can be retained. Meanwhile, the defect rate is reduced to minimum. The horizontal LED, which is fabricated with the patterned substrate of the instant disclosure, has higher luminance. The gaps among the protrusions facilitate light emitting from the LED and increase light output. The vertical LED, which is fabricated with the patterned substrate of the instant disclosure, is more cost effective. The gaps serve as channels for filling chemicals and separate the substrate and the LED structure. In this regard, the conventional laser peeling can be effectively replaced by the chemical peeling to reduce cost.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A patterned substrate comprising:
a substrate; and
a plurality of protrusions formed on the substrate, each of the protrusions having a top face and a base and each pair of immediately adjacent protrusions being minimally spaced by 0 to 0.2 μm.

2. The patterned substrate according to claim 1, wherein when the minimal distance between the pair of immediately adjacent protrusions is 0 μm, the bases thereof contact each other.

3. The patterned substrate according to claim 1, wherein the substrate is made of sapphire substrate, silicone substrate or silicone carbide substrate.

4. The patterned substrate according to claim 1, wherein the diameter of the top face and the distance between each pair of immediately adjacent top faces having a ratio between 1/5 to 5.

5. The patterned substrate according to claim 1, wherein the distance between each pair of immediately adjacent top faces is equal to or less than 10 μm.

6. The patterned substrate according to claim 1, wherein each protrusion resembles a polyhedron, the top face is truncated flat, the base defines a plurality of base corners and a plurality of base sides, and each of the base corners contacts or is proximate to the neighboring base corners or base sides.

7. The patterned substrate according to claim 1, wherein each of the protrusions resembles a cone, the top face is truncated flat, the base defines a round edge, each of the base edges contacts or is proximate to the neighboring base edges, and the protrusions are arranged in matrix or in alternative.

8. The patterned substrate according to claim 1, wherein each of the protrusions resembles an elongated trapezoidal body, the top face is truncated flat, the lengthwise sides of each of the bases define two base sides, and the two base sides of each of the protrusions contact or are proximate to the neighboring base sides.

9. A LED structure comprising:
a substrate;
a plurality of protrusions formed on the substrate, each of the protrusions having a top face and a base, each pair of immediately adjacent protrusions being minimally spaced by 0 to 0.2 μm and a gap defined therebetween;
a first semiconductor layer laminated on the substrate and covering the protrusions;
a light emitting layer laminated on a portion of the first semiconductor layer;
a second semiconductor layer laminated on the light emitting layer;
a first electrode disposed on the remaining portion of the first semiconductor layer in which the light emitting layer being absent; and
a second electrode disposed on the second semiconductor layer;
wherein when the minimal distance between the pair of immediately adjacent protrusions is 0 μm, the bases thereof contact each other.

10. The LED structure according to claim 9, wherein the substrate is made of sapphire substrate, silicone substrate or silicone carbide substrate.

11. The LED structure according to claim 9, wherein each of the protrusions resembles a polyhedron, the top face is truncated flat, the base defines a plurality of base corners and a plurality of base sides, and each of the base corners contacts or is proximate to the neighboring base corners or base sides.

12. The LED structure according to claim 9, wherein each of the protrusions resembles a cone, the top face is truncated flat, the base defines a round edge, each of the base edges contacts or is proximate to the neighboring base edges, and the protrusions are arranged in matrix or in alternative.

13. The LED structure according to claim 9, wherein each of the protrusions resembles an elongated trapezoidal body, the top face is truncated flat, the lengthwise sides of each of the bases define two base sides, and the two base sides of each of the protrusions contact or are proximate to the neighboring base sides.

14. A LED structure comprising:
a substrate;
a plurality of protrusions formed on the substrate, each of the protrusions having a top face and a base, each pair of immediately adjacent protrusions being minimally spaced by 0 to 0.2 μm and a gap defined therebetween;
a first semiconductor layer laminated on the substrate and covering the protrusions;
a light emitting layer laminated on a portion of the first semiconductor layer;
a second semiconductor layer laminated on the light emitting layer; and
a first electrode disposed on the second semiconductor layer;
wherein when the minimal distance between the pair of immediately adjacent protrusions is 0 μm, the bases thereof contact each other.

15. The LED structure according to claim 14, wherein the substrate is made of sapphire substrate, silicone substrate or silicone carbide substrate.

16. The LED structure according to claim 14, wherein each of the protrusions resembles a polyhedron, the top face is truncated flat, the base defines a plurality of base corners and a plurality of base sides, and each of the base corners contacts or is proximate to the neighboring base corners or base sides.

17. The LED structure according to claim 14, wherein each of the protrusions resembles a cone, the top face is truncated flat, the base defines a round edge, each of the base edges contacts or is proximate to the neighboring base edges, and the protrusions are arranged in matrix or in alternative.

18. The LED structure according to claim 14, wherein each of the protrusions resembles an elongated trapezoidal body, the top face is truncated flat, the lengthwise sides of each of the bases define two base sides, and the two base sides of each of the protrusions contact or are proximate to the neighboring base sides.
